(19) United States
(12) Patent Application Publication
(10) Pub. No.: US 2005/0230679 A1
(43) Pub. Date: Oct. 20, 2005

(54) Semiconductor device

(75) Inventors: Issei Yonemoto, Yamato-shi (JP); Mutsuo Mitsui, Hachioji-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/100,578

(22) Filed: Apr. 7, 2005

(30) Foreign Application Priority Data
Apr. 14, 2004 (JP) 2004-119250

(51) Int. Cl. H01L 35/24

(52) U.S. Cl. 257/40

(57) ABSTRACT

A semiconductor device with a configuration having a high sealing capability using a ultraviolet curing resin is provided, wherein a cover and a substrate contact each other, and the ultraviolet cured resin is disposed on the contacting end of both and cured.

### BACKGROUND OF THE INVENTION

1. Field of the Invention

The present invention relates to a semiconductor device having elements sealed by a cover. More particularly, it relates to an organic light emitting device having organic light emitting elements.

2. Related Background Art

An organic light emitting device disclosed in Japanese Patent Application Laid-Open No. 2001-217073 (p. 3, FIG. 2) will be taken up. FIG. 5 is a diagram showing a conventional technology. FIG. 5 is a sectional view of the organic electroluminescent device. Reference numeral 51 is a base plate; 52 is first electrodes; 54 is an insulating layer; 55 is a positive hole transport layer; 56 is a light emitting layer; 57 is an electron transport layer; 58 is second electrodes; 510 is a thin film layer; 522 is lead-out electrodes for the second electrodes; 523 is connecting parts; 524 is an adhesive; 525 is a sealed space; and 526 is a sealing plate.

Organic EL elements are composed of the first electrodes 52, the second electrodes 58 and the organic layer (the thin film layer 510) disposed therebetween. The second electrodes 58 are connected at the connecting parts 523 to the lead-out electrodes 522 for the second electrodes, which are connectable to the exterior of the organic electroluminescent device.

The organic EL elements use the adhesive 524 as a sealing material and are separated from the outside, and are disposed in the sealed space 525 between the base plate 51 and the sealing plate 526.

The adhesive 524 is coated on the outside periphery of a light emitting area (the organic EL elements) to seal and fix the sealing plate 526 on the base plate.

It is also described that the adhesive means favorably employs a curable resin or a plastic resin, which can relatively easily provide a great effect without the necessity for a high temperature process of 200° C. or higher. A known material can be used as the curable resin, such as epoxides, silicones, acrylics or urethanes. Examples of curing methods include the ultraviolet irradiation method, the thermosetting method and the hardener mixing method.

As shown in the figure, the adhesive is disposed between the sealing plate 526 and the base plate 51, i.e. directly under the sealing plate 526.

In such configuration, when an ultraviolet cured resin is used as an adhesive, sufficient light to cure the adhesive is difficult to irradiate on the adhesive. More specifically, when light is irradiated from the intraplane direction of the base plate, the light must be irradiated on every side of the sealing plate where the adhesive is disposed. Or, when at least either of the base plate and the sealing plate is a light transmitting member, and light is irradiated from the light transmitting member side, the light cannot reach the adhesive without transmitting through the light transmitting member, sometimes resulting in insufficient curing of the adhesive.

### SUMMARY OF THE INVENTION

The present invention has an object to solve such problems, and an object to provide a semiconductor device in which effective sealing by an ultraviolet cured resin is conducted.

Therefore, the present invention provides a semiconductor device comprising elements having a semiconductive conductor, a substrate on which the elements are mounted and a cover which holds the elements between itself and the substrate, wherein the end part of the cover contacts directly with the substrate, and a ultraviolet cured resin is disposed both on the end part and the substrate.

According to the present invention, a semiconductor device in which effective sealing by an ultraviolet resin is conducted can be provided.

### BRIEF DESCRIPTION OF THE DRAWINGS

FIG. 1 is a front schematic view of the display that is the organic light emitting device according to the embodiments;

FIG. 2 is a sectional view of the display taken through line 2-2 of FIG. 1 according to the first embodiment;

FIG. 3 is a sectional view of the display taken through line 3-3 of FIG. 1 according to the first embodiment;

FIG. 4 is a sectional view of the display taken through line 2-2 of FIG. 1 according to the second embodiment; and

FIG. 5 is a diagram illustrating the related background art.

### DETAILED DESCRIPTION OF THE PREFERRED EMBODIMENTS

The semiconductor device according to the present invention is characterized by that the cover and the substrate contact each other, where the ultraviolet cured resin is disposed.

The embodiments embody an organic light emitting device as one form of the semiconductor device. The organic light emitting device is one having organic light emitting elements (organic electroluminescent elements).

Reference numerals used in the figures will be described below before they are referred to.

### First Embodiment

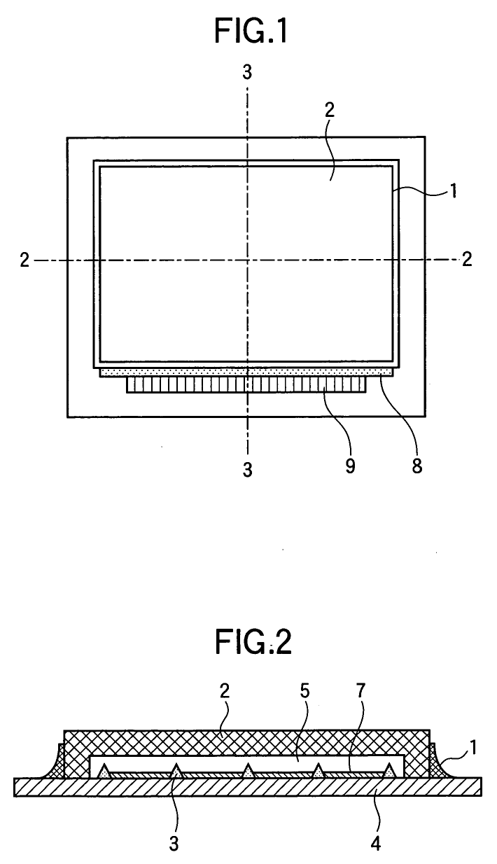

FIG. 1 is a front schematic diagram showing the organic light emitting device according to this embodiment.

Reference numeral 1 is the ultraviolet cured resin; 2 is the cover; 8 is an insulating film; and 9 is lead-out electrodes.

The organic light emitting device is provided with the organic light emitting elements on a base plate. The plurality of the organic light emitting elements (not shown in the figure) are disposed inside the area where the cover 2 is installed. In this embodiment, a full-color display is taken up, in which an organic light emitting element is installed in each pixel, which emits one of luminescent colors of red, green and blue (RGB).

The organic light emitting element has an organic layer between a pair of electrodes and is an element emitting light by charges (electrons or holes) supplied to the organic layer. The conductivity of the organic layer is the same as that of a semiconductor. Therefore, this embodiment employs the organic light emitting elements as one example of elements having a semiconductive conductor.

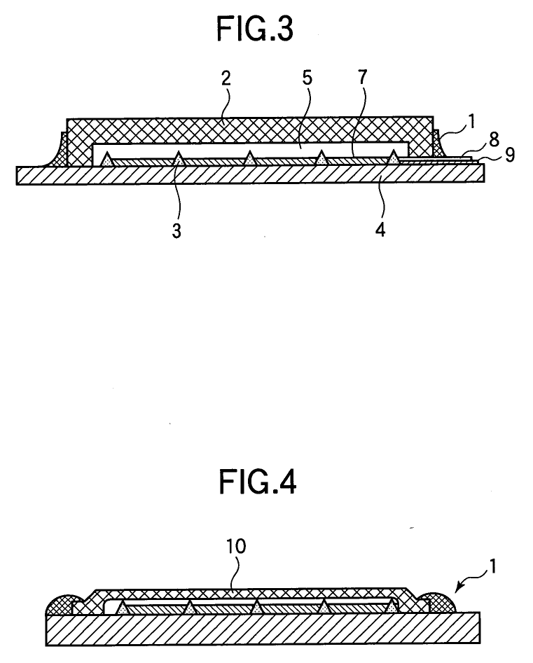

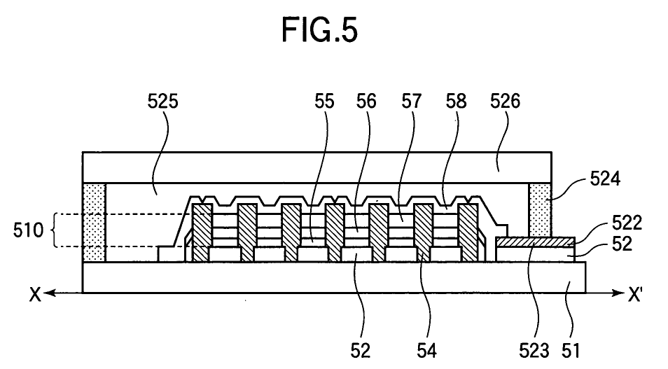

FIG. 2 and FIG. 3 are sectional views of the organic light emitting device illustrated in FIG. 1 taken through lines 2-2 and 3-3, respectively.

Reference numeral 3 is element separating films; 4 is the base plate that is the substrate; 5 is a recess; and 7 is the organic light emitting elements that are semiconductor elements.

As shown in FIG. 2, an ultraviolet cured resin 1 is disposed on the left and right ends in the sectional direction of line 2-2 of FIG. 1. The ultraviolet cured resin 1 is disposed on side-walls of the cover 2. The cover 2 has the recess 5, and the plurality of the organic light emitting elements 7 are disposed between the recess 5 and the base plate 4. The cover 2 contacts directly with the base plate 4 outside the recess, and the ultraviolet cured resin 1 is not disposed in the contact interface of the cover 2 and the base plate 4. This is due to that the ultraviolet cured resin 1 is disposed and cured on the side-walls of the cover 2 and the base plate 4 in the state that the cover 2 and the base plate 4 contact each other.

The ultraviolet cured resin 1 is thus disposed, so the cover 2 and the base plate 4 can be sealed without disposing the ultraviolet cured resin 1 in the interface of the cover 2 and the base plate 4.

By disposing the ultraviolet cured resin on such position, the ultraviolet cured resin 1 is not disposed directly under or directly over the cover 2 or the base plate 4. Consequently, after the ultraviolet cured resin 1 is disposed on the above described position, light is irradiated not through the cover 2 or the base plate 4 but directly on the ultraviolet cured resin, thereby allowing efficient curing of the ultraviolet cured resin.

In this embodiment, besides, the ultraviolet cured resin 1 is disposed on a plurality of sides of the cover 2 (more favorably, all sides). Therefore, light can be irradiated at a time from the side of disposing the cover to the ultraviolet cured resin disposed on each side.

In the organic light emitting device according to this embodiment, the cover 2 is in a shape having the recess 5. This embodiment employs a glass in a thickness of causing little deflection for the cover 2. The recess 5 is provided by the etching process, etc. The thickness of the cover 2 is 1.1 mm and the thickness of the recess 5 is 0.4 mm. The thickness of the cover 2 over the recess 5 is thus 0.7 mm.

The widths of the cover 2 contacting with the base plate 4 on the left and right in the figure are each 2 mm. The ultraviolet cured resin 1 is disposed in 0.5 mm in the intraplane direction (left and right direction in the figure) of the base plate 4.

The plurality of the organic light emitting elements 7 are disposed between the recess 5 and the base plate 4. Each organic light emitting element is separated from another by the element-separating film 3. In this embodiment, a space between the recess 5 and the base plate 4 is in a vacuum or filled with an inert gas.

FIG. 3 is a sectional diagram of the organic light emitting device described in FIG. 1 taken through line 3-3 in FIG. 1. The disposition of the ultraviolet cured resin 1 shown on the left in FIG. 3 is the same as that above described referring to FIG. 2. The ultraviolet cured resin 1 on the right in FIG. 3 is disposed above the lead-out electrodes 9. More specifically, the insulating film 8 is disposed on the lead-out electrodes 9. The ultraviolet cured resin 1 is disposed on the insulating film 8 and the side-walls of the cover 2. Also in this configuration, the cover 2 may well be said to be disposed in contact with the substrate. This is because, with the cover 2 being not in contact with the base plate 4 and being in contact with the insulating film 8, the counterpart to contact with the cover 2 does not necessarily need to be a base plate, and the insulating film 8 is the counterpart contacting with the cover 2 as a substrate. With such configuration, the ultraviolet cured resin 1 does not penetrate the clearance between the cover 2 and the insulating film 8.

The cover 2 is not disposed directly in contact with the lead-out electrodes. By disposing the insulating film 8 between both, penetrating of water from the outside along the lead-out electrodes 9 into the recess 5 is prevented. Besides, the direct contact of the cover 2 with the insulating film 8 compares favorably with that with the lead-out electrodes 9, because the former hardly yields a gap in the interface. Therefore, for example, for the configuration which has a plurality of irregularities due to the thickness of the plurality of the lead-out electrodes disposed on one side as in this embodiment, the cover 2 is favorably disposed in contact with the insulating film 8. Besides, the ultraviolet cured resin 1 is more favorably disposed in contact with the insulating film 8 extending from directly under the cover 2 to the exterior than in contact with the lead-out electrodes 9. In this case, as shown in the figure, the lead-out electrodes are configured to extend further out of the insulating film 8 and connect to exterior terminals at a part exposed out of the insulating film 8.

In this embodiment, the ultraviolet cured resin may be disposed on the entire circumference or any one side of the cover.

In this embodiment, the cover 2 is the etched member. However, the present invention is not limited to it so long as a recess exists. For example, a member constituting side-walls and a base material constituting a ceiling plate may be different bodies.

As the cover of this embodiment is used a glass, which only exemplifies a material inflexible in such a thickness, but other appropriate materials can be certainly used. Light transmitting materials may be optionally used as the cover. Glass is, however, favorable in terms of being hardly flexible even in a thin shape and having high moisture- and oxygen-proof performance. Further, in the configuration wherein organic light emitting elements emit light through the cover 2, and switching elements such as TFT to control light-emission and nonemission of each organic light emitting element are disposed on a substrate side, glass is a material favorably used as the cover 2.

The organic light emitting device according to this embodiment can be used not only as a display, but also as a light source to irradiate light on a photoconductor of an electrophotographic imaging device such as a laser beam printer or a copying machine.

This embodiment has been described with the organic light emitting device. The present invention is, however, applicable to semiconductor devices necessitating high-performance sealing other than the organic light emitting device. For example, it is applicable to a semiconductor device having organic semiconductors such as transistors in which an organic substance is used as a semiconductor layer.

### Second Embodiment

The organic light emitting device according to this second embodiment is characterized by that it has the end part of a cover contacting with a substrate by its own weight. Except that, this embodiment is practiced as in the first embodiment. FIG. 4 is a sectional diagram schematically showing the organic light emitting device according to the second embodiment. This sectional direction is the same as the line 3-3 sectional direction in FIG. 1. Reference numeral 10 in the figure indicates a film. As shown in the figure, the end part (left and right ends in the figure) of the film contacts with the base plate that is the substrate. Since the film is a thin one, the end part thereof other than the part over the organic light emitting elements bends by its own weight and contacts with the base plate. The film may be a thin glass or a cycloolefin polymer film, etc. The point different from the first embodiment is that the cover according to this embodiment is not provided with a recess for containing organic light emitting elements and is a sheet-like film flat from the end part of the cover to its central part. That is, the cover profiles the substrate surface and the shape of the organic light emitting elements, and is disposed in contact with them. The cover is very thin as it is a film. More specifically, the thickness is as thin as 0.3 mm, much thinner than that of the cover described in the first embodiment. The cover in this embodiment does not need to have a configuration in which its side-walls can be clearly identified. In this embodiment, the ultraviolet cured resin covers the substrate and the upper surface of the cover end part. However, since the ultraviolet cured resin is disposed and cured in the state that the substrate and the cover contact each other, it does not penetrate into the clearance between the cover and the substrate. Since the ultraviolet cured resin is disposed on the upper surface of the cover end part and the substrate, it can be said to be naturally in contact with the cover side-wall (since it is very thin, it can be rephrased as a side part).

In the organic light emitting device according to this embodiment, the ultraviolet cured resin can be disposed on the insulating film on the lead-out electrodes in the line 2-2 sectional diagram in FIG. 1 as in the first embodiment. Here, the end part of the cover is disposed by its own weight in contact with the insulating film that is the substrate.

The end part of the cover is disposed by its own weight on the substrate in this embodiment. To make this end part more closely adhere to the substrate, both of them are contacted favorably under a reduced-pressure environment such as under vacuum. Both of them can more closely adhere to each other when they are exposed to a high pressure environment (e.g. ordinary pressure) after the contact under the reduced-pressure environment. The ultraviolet cured resin may be disposed under a reduced-pressure environment or a high pressure environment. The ultraviolet cured resin may be cured under a reduced-pressure environment or a high pressure environment.

Examples will be described as follows.

### EXAMPLE 1

This example relates to sealing of the organic light emitting device according to the first embodiment.

The ultraviolet cured resin was disposed on the cover having the thickness described hereinbefore.

The ultraviolet cured resin was disposed in a width in the base plate of 0.5 mm on the entire circumference by dispensor-coating. The entire circumference coating was performed with a needle inner diameter of 0.41 mm, a coating pressure of 240 Pa and a coating velocity of 10 mm/sec, and with the needle at a bevel of 45 degrees, a gap of 20 microns between the needle tip and the etched glass 2 and a gap of 20 microns between the needle tip and the surface of the base plate 4. Then, with a light-shielding mask installed on the plane of the organic light emitting elements, UV-light (ORC Manufacturing Co., Ltd. HANDY UV500) was irradiated in an illuminance of 80 mW/cm² for 5 minutes on the surface of the sealing material for curing. The sealing performance of the panel was indirectly measured by installing a dew-point instrument in a space of a SUS fixture directly connected to the recess and measuring the change in dew-point in the space. As a result, with an initial panel sealing environment of −80° C., a dew-point of −75° C. or lower was held after 3000 hours (4 months), which confirmed that the sealing material has a high capability of maintaining the space dew-point.

### EXAMPLE 2

This example relates to the organic light emitting device according the second embodiment. Except that, it is practiced as in example 1. A film-like glass plate of 0.3 mm in thickness was used for the cover. The glass plate has such a length of 5 mm (length in the intraplane direction of the base plate) that the end part of the glass plate contacts by its own weight with the base plate or insulating film that are the substrates.

The irradiated UV-light is the same as in example 1. As a result, the capability of maintaining the space dew-point similar to example 1 was obtained.

### COMPARATIVE EXAMPLE 1

This comparative example is for explaining the comparison between examples 1 and 2.

In an organic light emitting device in which organic light emitting elements are interposed between a glass plate with no recess and a base plate, which do not contact each other, a ultraviolet cured resin is disposed between the glass plate and the base plate, and cured.

As a result, an initial panel sealing environment of −80° C. could be held for 180 hours, but after that, deterioration was observed, which confirmed the low capability of maintaining the space dew-point.

This application claims priority from Japanese Patent Application No. 2004-119250 filed Apr. 14, 2004, which is hereby incorporated by reference herein.

1. A semiconductor device comprising: an element having a semiconductive conductor; a substrate on which the element is mounted; and a cover which holds the element between itself and the substrate, wherein
the end part of the cover contacts directly with the substrate, and
a ultraviolet cured resin is disposed on both the end part and the substrate.

2. The semiconductor device according to claim 1, wherein the ultraviolet cured resin is disposed on the substrate and on a side-wall only of the end part of the cover.

3. The semiconductor device according to claim 2, wherein the cover has a recess, and wherein the element is disposed between the recess and the substrate.

4. The semiconductor device according to claim 1, wherein the cover is a film having no recess, and wherein the end part bends by its own weight to contact with the substrate.

5. The semiconductor device according to claim 1, wherein the element is an organic light emitting element comprising a pair of electrodes and at least one organic layer that is the conductor disposed between the pair of the electrodes.
